(19) United States
(12) Patent Application Publication
(10) Pub. No.: US 2026/0040801 A1
(43) Pub. Date: Feb. 5, 2026

(54) POLARIZING FILM, DISPLAY APPARATUS INCLUDING THE SAME, AND ELECTRONIC DEVICE INCLUDING THE SAME

(71) Applicant: Samsung Display Co., Ltd., Yongin-si (KR)

(72) Inventors: Beonghun Beon, Yongin-si (KR); Dukjin Lee, Yongin-si (KR); Yeonsu Woo, Yongin-si (KR); Woosuk Jung, Yongin-si (KR)

(21) Appl. No.: 19/282,688

(22) Filed: Jul. 28, 2025

(30) Foreign Application Priority Data
Aug. 2, 2024 (KR) 10-2024-0103273

(51) Int. Cl. H10K 59/80; G02B 5/30

(52) U.S. Cl. CPC H10K 59/8791; G02B 5/3025; G02B 5/3083

(57) ABSTRACT

A polarizing film, a display apparatus including the polarizing film, and an electronic device including the display apparatus are disclosed. The display apparatus may include a display panel including a display element and a polarizing film on the display panel. The polarizing film may include a first phase retardation layer, a second phase retardation layer on the first phase retardation layer, a first adhesive layer between the first phase retardation layer and the second phase retardation layer, a second adhesive layer on the second phase retardation layer, a first protective layer on the second adhesive layer, a second protective layer on the first protective layer, and a polarizing layer between the first protective layer and the second protective layer. A refractive index of the first adhesive layer may be about 1.55 to about 1.7.

### CROSS-REFERENCE TO RELATED APPLICATION

The present application claims priority to and the benefit of Korean Patent Application No. 10-2024-0103273, filed on Aug. 2, 2024, in the Korean Intellectual Property Office, the entire disclosure of which is incorporated herein by reference.

### BACKGROUND

### 1. Field

One or more embodiments of the present disclosure relate to a polarizing film, a display apparatus including the polarizing film, and an electronic device including the display apparatus, and, for example, to a polarizing film to protect a screen from external light reflection so that a display apparatus may display high-quality images, a display apparatus including the polarizing film, and an electronic device including the display apparatus.

### 2. Description of the Related Art

Display apparatuses, such as liquid crystal displays (LCD), organic light-emitting displays (OLED), and electrophoretic displays (EPD), are configured or arranged to implement display images. Such a display apparatus includes a polarizing film to prevent external light from being reflected from the front of the display apparatus (or to reduce a degree to or occurrence of which external light reflects from the front of the display apparatus).

### SUMMARY

Hereinafter, embodiments of the present disclosure will be described in more detail. However, these embodiments are examples, the present disclosure is not limited thereto, and the present disclosure is defined by the scope of the appended claims and equivalents thereof.

One or more aspects of embodiments of the present disclosure are directed toward a polarizing film having excellent or suitable anti-reflection characteristics and reflection saturation characteristics and a display apparatus including the polarizing film.

Additional aspects of embodiments will be set forth in part in the description which follows and, in part, will be apparent from the description, or may be learned by practice of the presented embodiments of the disclosure.

According to one or more embodiments, a display apparatus includes a display panel including a display element, and a polarizing film on the display panel, wherein the polarizing film includes a first phase retardation layer, a second phase retardation layer on the first phase retardation layer, a first adhesive layer between the first phase retardation layer and the second phase retardation layer, a second adhesive layer on the second phase retardation layer, a first protective layer on the second adhesive layer, a second protective layer on the first protective layer, and a polarizing layer between the first protective layer and the second protective layer, wherein a refractive index of the first adhesive layer is about 1.55 to about 1.7.

In one or more embodiments, a thickness of the first adhesive layer may be about 5 μm to about 10 μm.

In one or more embodiments, the first phase retardation layer may include a quarter-wave plate (QWP), and the second phase retardation layer may include a half-wave plate (HWP).

In one or more embodiments, the first phase retardation layer may include a positive C plate, and the second phase retardation layer may include an HWP.

In one or more embodiments, the first phase retardation layer may include a positive A plate, and the second phase retardation layer may include a negative A plate.

In one or more embodiments, the first adhesive layer may be on a surface of the first phase retardation layer, and a phase compensation layer may be on another surface of the first phase retardation layer.

In one or more embodiments, the phase compensation layer may include a positive C plate.

In one or more embodiments, the first adhesive layer may include a base polymer and a refractive index modifier, and the refractive index modifier may include a compound having an aromatic ring.

In one or more embodiments, a refractive index of the refractive index modifier may be about 1.55 to about 2.0.

In one or more embodiments, the refractive index modifier may include at least one selected from among 9,9-bis(4-hydroxyphenyl)fluorene, 9,9-bis(4-aminophenyl)fluorene, 6-acryloyloxy methyl dinaphthothiophene, 6-methacryloyloxy methyl zinaphthothiophene, 5-acryloyloxy ethyl dinaphthothiophene, 6-acryloyloxy ethyl dinaphthothiophene, 6-vinyl dinaphthothiophene, 5-vinyl dinaphthothiophene, and 2,12-diarylooxyginafutothiophene.

In one or more embodiments, the first adhesive layer may have a refractive index greater than a refractive index of the second adhesive layer.

In one or more embodiments, a refractive index of each of the first phase retardation layer and the second phase retardation layer may be about 1.6 to about 1.7.

In one or more embodiments, the first adhesive layer may further include an ultraviolet (UV) curable material.

According to one or more embodiments, a polarizing film includes a first phase retardation layer, a second phase retardation layer on the first phase retardation layer, a first adhesive layer between the first phase retardation layer and the second phase retardation layer, a second adhesive layer on the second phase retardation layer, a first protective layer on the second adhesive layer, a second protective layer on the first protective layer, and a polarizing layer between the first protective layer and the second protective layer, wherein a refractive index of the first adhesive layer is about 1.55 to about 1.7.

In one or more embodiments, the first adhesive layer may include a base polymer and a refractive index modifier, and the refractive index modifier may include a compound having an aromatic ring.

In one or more embodiments, a refractive index of the refractive index modifier may be about 1.55 to about 2.0.

In one or more embodiments, the refractive index modifier may include at least one selected from among 9,9-bis(4-hydroxyphenyl)fluorene, 9,9-bis(4-aminophenyl)fluorene, 6-acryloyloxy methyl dinaphthothiophene, 6-methacryloyloxy methyl zinaphthothiophene, 5-acryloyloxy ethyl dinaphthothiophene, 6-acryloyloxy ethyl dinaphthothiophene, 6-vinyl dinaphthothiophene, 5-vinyl dinaphthothiophene, and 2,12-diarylooxyginafutothiophene.

In one or more embodiments, the first adhesive layer may have a refractive index greater than a refractive index of the second adhesive layer.

In one or more embodiments, a refractive index of each of the first phase retardation layer and the second phase retardation layer may be about 1.6 to about 1.7.

In one or more embodiments, the first adhesive layer may further include an ultraviolet (UV) curable material.

According to one or more embodiments, an electronic device includes the display apparatus as described in one or more embodiments.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

However, aspects and features of embodiments of the present disclosure are not restricted to the one set forth herein. The above and other aspects and features of certain embodiments of the present disclosure will become more apparent to one of ordinary skill in the art to which the present disclosure pertains by referencing the detailed description of the present disclosure given.

These general and specific aspects and features of embodiments of the present disclosure may be practiced by using systems, methods, computer programs, or any combination thereof.

### BRIEF DESCRIPTION OF THE DRAWINGS

The above and other aspects and features of certain embodiments of the present disclosure will become more apparent from the following description taken in conjunction with the accompanying drawings, in which:

FIG. 1 is a schematic plan view of a display apparatus according to one or more embodiments;

FIG. 2 is a schematic cross-sectional view of the display apparatus according to one or more embodiments;

FIG. 3 is a schematic cross-sectional view of a polarizing film according to one or more embodiments;

FIG. 4 is a schematic cross-sectional view of a polarizing film according to one or more embodiments;

FIGS. 5 and 6 are cross-sectional views illustrating portions of polarizing films of Comparative Example and Example, respectively, and illustrating interface reflection;

FIG. 7 is a schematic cross-sectional view of a polarizing film according to one or more embodiments; and

FIG. 8 is a schematic cross-sectional view of a portion of a display apparatus according to one or more embodiments.

### DETAILED DESCRIPTION

Reference will be made in more detail to one or more embodiments, examples of which are illustrated in the accompanying drawings, wherein like reference numerals refer to like elements throughout. In this regard, the subject matter of the present disclosure may be embodied in different forms and should not be construed as being limited to one or more embodiments set forth herein. Rather, these embodiments are provided as examples, by referring to the figures, to explain aspects and features of the present disclosure to those skilled in the art.

As used herein, the term “and/or” includes any and all combinations of one or more of the associated listed items. Throughout the present disclosure, the expression “at least one of a, b, or c” indicates only a, only b, only c, both a and b, both a and c, both b and c, all of a, b, and c, or variations thereof.

As the present description allows for one or more suitable changes and embodiments, certain embodiments will be illustrated in the accompanying drawings and described in more detail in the written description. The aspects, effects, and features of the present disclosure and methods of achieving them will be clarified with reference to one or more embodiments and the accompanying drawings as described below in more detail. However, the disclosure is not limited to the disclosed embodiments and may be embodied in one or more suitable forms.

Hereinafter, certain embodiments will be described in more detail with reference to the accompanying drawings. If (e.g., when) describing one or more embodiments with reference to the accompanying drawings, substantially the same or corresponding elements are denoted by the same reference numerals, and redundant descriptions thereof may not be provided.

It will be understood that the terms “first,” “second,” and/or the like may be used herein to describe one or more suitable elements, but these elements should not be limited by these terms. These terms are only used to distinguish one element from another.

The singular forms as used herein are intended to include the plural forms as well unless the context clearly indicates otherwise.

The utilization of “may” if (e.g., when) describing embodiments of the present disclosure refers to “one or more embodiments of the present disclosure.”

It will be further understood that the terms “include/have” and/or “including/having” used herein specify the presence of stated features or elements, but do not preclude the presence or addition of one or more other features or elements.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the term “about” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and refers to within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, 20%, 10%, or ±5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

It will be further understood that, if (e.g., when) a layer, a region, or an element is referred to as being “on” another layer, region, or element, it may be directly or indirectly on the other layer, region, or element. For example, intervening layers, regions, or elements may be present therebetween. In contrast, if (e.g., when) an element is referred to as being “directly on” another element, there are no intervening elements present therebetween.

It will be further understood that if (e.g., when) layers, regions, or elements are referred to as being connected to each other, they may be directly connected to each other or indirectly connected to each other with intervening layers, regions, or elements therebetween. For example, if (e.g., when) layers, regions, or elements are referred to as being electrically connected to each other, they may be directly electrically connected to each other or indirectly electrically connected to each other with intervening layers, regions, or elements therebetween.

Throughout the disclosure, the expression “at least one of A and B”, “at least one selected from among A and B” or “A and/or B” refers to only A, only B, or both A and B.

In the present disclosure, the x-axis, the y-axis, and the z-axis are not limited to three axes of the rectangular coordinate system and may be interpreted in a broader sense. For example, the x-axis, the y-axis, and the z-axis may be perpendicular (e.g., substantially perpendicular) to one another or may represent different directions that are not perpendicular to one another.

If (e.g., when) a certain embodiment is implemented differently, a set or specific process order may be performed differently from the described order. For example, two consecutively described processes may be performed substantially at the same time or performed in an order opposite to the stated order.

Also, the sizes of elements in the drawings may be exaggerated or reduced to effectively illustrate the technical contents of the present disclosure. For example, because the sizes and thicknesses of elements in the drawings are arbitrarily illustrated to effectively illustrate the technical contents of the present disclosure, the disclosure is not necessarily limited thereto.

Unless otherwise defined, all terms (including technical and scientific terms) used herein have substantially the same meaning as generally understood by one of ordinary skill in the art to which the present disclosure belongs. It will be further understood that terms, such as those defined in dictionaries that are generally available or generally used, should be interpreted as having a meaning that is consistent with their meaning in the context of the relevant art and will not be interpreted in an idealized or overly formal sense unless expressly so defined herein.

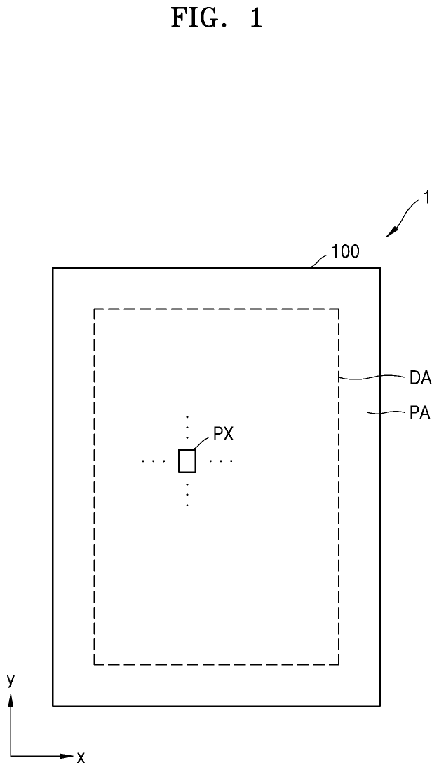

FIG. 1 is a plan view schematically illustrating a display apparatus 1 according to one or more embodiments.

Referring to FIG. 1, the display apparatus 1 may include a display area DA and a peripheral area PA. In one or more embodiments, the display apparatus 1 may include a substrate 100. In one or more embodiments, the substrate 100 may include the display area DA and the peripheral area PA.

A plurality of pixels PX may be in the display area DA of the substrate 100. Each of the plurality of pixels PX may include a display element, such as an organic light-emitting diode. The pixel PX may further include a plurality of thin-film transistors and storage capacitors to control the display element. The number of thin-film transistors included in one pixel PX may be suitably changed. For example, the number of thin-film transistors included in one pixel PX may be 1 to 7.

One or more suitable wirings configured or arranged to transmit electrical signals to be applied to the display area DA may be in the peripheral area PA of the substrate 100. Thin-film transistors may also be in the peripheral area PA. In one or more embodiments, the thin-film transistors in the peripheral area PA may be a portion of a circuit configured or arranged to control electrical signals to be applied to the display area DA.

Hereinafter, an organic light-emitting display apparatus is described as an example of the display apparatus 1 according to one or more embodiments, but embodiment of the present disclosure are not limited thereto. Examples of the display apparatus 1 may include an inorganic electroluminescence (EL) display (or an inorganic light-emitting display), a quantum dot light-emitting display, and/or the like.

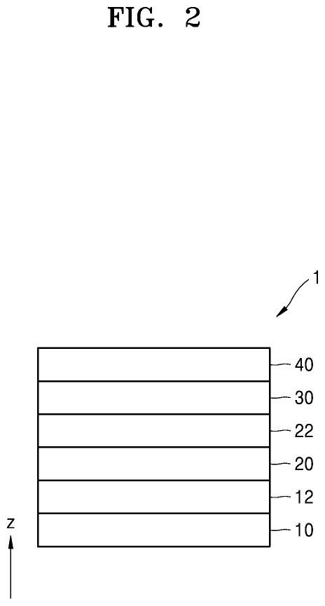

FIG. 2 is a schematic cross-sectional view of the display apparatus 1 according to one or more embodiments.

Referring to FIG. 2, the display apparatus 1 according to one or more embodiments may further include a display panel 10, a polarizing film 20, a cover window 30, and a functional coating layer 40.

As described with reference to FIG. 1, the display panel 10 may include the pixels PX on the substrate 100 and each including a display element. The display panel 10 may display an image by externally emitting light through the pixels PX.

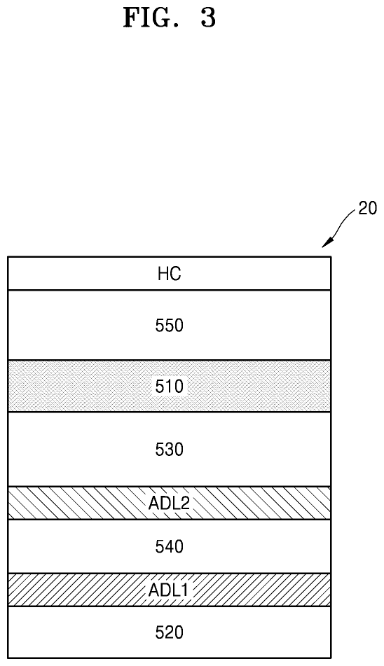

The polarizing film 20 may be on the display panel 10. The polarizing film 20 is described in more detail below with reference to FIG. 3.

A third adhesive layer 12 may be between the polarizing film 20 and the display panel 10. The third adhesive layer 12 may be a pressure sensitive adhesive (PSA).

The cover window 30 may be on the polarizing film 20. The cover window 30 may protect the display panel 10 and polarizing film 20 therebelow. The cover window 30 may have relatively high transmittance to transmit light emitted from the display panel 10. In one or more embodiments, the cover window 30 may have a transmittance of about 85% or more and a transmission haze of about 2% or less, but embodiments of the present disclosure are not limited thereto.

A fourth adhesive layer 22 may be between the polarizing film 20 and the cover window 30. The fourth adhesive layer 22 may be an optically clear (e.g., substantially clear) adhesive (OCA).

The functional coating layer 40 may be on the cover window 30. The functional coating layer 40 may include one or more suitable layers to protect the cover window 30 and improve or enhance the visibility of light emitted from the display panel 10. For example, the functional coating layer 40 may include an anti-finger (AF) coating layer, an anti-reflection (AR) coating layer, an anti-glare (AG) coating layer, and/or the like.

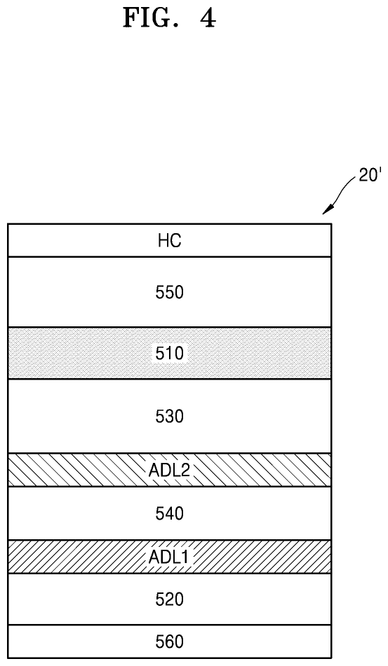

FIG. 3 is a schematic cross-sectional view of a polarizing film 20 according to one or more embodiments, and FIG. 4 is a schematic cross-sectional view of a polarizing film 20′ according to one or more embodiments.

Referring to FIG. 3, the polarizing film 20 according to one or more embodiments may include a polarizing layer 510, a first phase retardation layer 520, a second phase retardation layer 540, a first protective layer 530, a second protective layer 550, a hard coating layer HC, a first adhesive layer ADL1 between the first phase retardation layer 520 and the second phase retardation layer 540, and a second adhesive layer ADL2 on the second phase retardation layer 540.

In one or more embodiments, the polarizing layer 510 may be configured or arranged to polarize light incident from a light source into light substantially in the same direction as a polarization axis. The polarizing layer 510 may be formed or provided by including a polarizer and/or a dichroic dye in a polyvinyl alcohol (PVA) film. The dichroic dye may be iodine molecules and/or dye molecules.

In one or more embodiments, the polarizing layer 510 may be formed or provided by stretching a PVA film in one direction and immersing the PVA film in a solution of iodine and/or a dichroic dye. In one or more embodiments, iodine molecules and/or dichroic dye molecules may be parallel (e.g., substantially parallel) to the stretching direction. Because the iodine molecules and dye molecules exhibit dichroism, the iodine molecules and dye molecules may absorb light that vibrates in the stretching direction and may transmit light that vibrates in a direction perpendicular (e.g., substantially perpendicular) to the stretching direction.

The first protective layer 530 and the second protective layer 550 may be respectively on the upper surface and the lower surface of the polarizing layer 510. The first protective layer 530 and the second protective layer 550 may support the polarizing layer 510 and supplement the mechanical strength of the polarizing layer 510. Each of the first protective layer 530 and the second protective layer 550 may include triacetyl cellulous (TAC), a cycloolefin polymer, polymethyl methacrylate (PMMA), polyethylene terephthalate (PET), and/or the like. FIG. 3 illustrates the polarizing film 20 including both the first protective layer 530 and the second protective layer 550, but in one or more embodiments, the second protective layer 550 may not be provided.

The first phase retardation layer 520 may be below the polarizing layer 510. For example, the first phase retardation layer 520 may be one of a positive A plate, a negative A plate, a positive C plate, or a negative C plate. In one or more embodiments, the first phase retardation layer 520 may be a quarter-wave plate (QWP) or a half-wave plate (HWP). The first phase retardation layer 520 may include polycarbonate (PC), TAC, and/or a cycloolefin polymer.

The second phase retardation layer 540 may be below the polarizing layer 510 and above the first phase retardation layer 520. For example, the second phase retardation layer 540 may be one of a positive A plate, a negative A plate, a positive C plate, or a negative C plate. In one or more embodiments, the second phase retardation layer 540 may be a QWP or an HWP. The second phase retardation layer 540 may include PC, TAC, and/or a cycloolefin polymer.

In one or more embodiments, if (e.g., when) the first phase retardation layer 520 includes a QWP, the second phase retardation layer 540 may include an HWP. In one or more embodiments, if (e.g., when) the first phase retardation layer 520 includes a positive C plate, the second phase retardation layer 540 may include a QWP.

In one or more embodiments, if (e.g., when) the first phase retardation layer 520 includes a positive A plate, the second phase retardation layer 540 may include a negative A plate. In one or more embodiments, the first phase retardation layer 520 and the second phase retardation layer 540 may be implemented as positive dispersion liquid crystals. In the present disclosure, a phase compensation layer 560 may be further below the first phase retardation layer 520 including the positive A plate, as illustrated in FIG. 4. The phase compensation layer 560 may include, for example, a positive C plate. In the present disclosure, the first protective layer 530 on the second phase retardation layer 540 may have a negative C phase and may serve as a reverse dispersion layer if (e.g., when) compensating for the side surface, thereby minimizing side color dispersion (or reducing a degree or occurrence of side color dispersion).

The first phase retardation layer 520 and the second phase retardation layer 540 may retard the phase of polarized light that passes through the polarizing layer 510. Light that passes through the first phase retardation layer 520 and the second phase retardation layer 540 may be circularly (e.g., substantially circularly) or elliptically (e.g., substantially elliptically) polarized. In one or more embodiments, the reflectance of light may be reduced. The first phase retardation layer 520 and the second phase retardation layer 540 may be farther away from a light source than the polarizing layer 510. For example, if (e.g., when) external light is incident from above the polarizing layer 510, the first phase retardation layer 520 and the second phase retardation layer 540 may be below the polarizing layer 510.

In one or more embodiments, a refractive index of the first phase retardation layer 520 and the second phase retardation layer 540 may be about 1.6 to about 1.7.

The first adhesive layer ADL1 may be between the first phase retardation layer 520 and the second phase retardation layer 540. The thickness of the first adhesive layer ADL1 may be about 5 μm to about 10 μm. It may be difficult to form or provide the first adhesive layer ADL1 having a thickness less than 5 μm, and if (e.g., when) the first adhesive layer ADL1 has a thickness less than 5 μm, the adhesive effect may be reduced. In one or more embodiments, if (e.g., when) the first adhesive layer ADL1 has a thickness greater than 10 μm, the overall thickness of the display apparatus (see 1 of FIG. 1) may increase, and the light transmittance may be reduced.

In one or more embodiments, the refractive index of the first adhesive layer ADL1 may be similar to the refractive indices of the first phase retardation layer 520 and the second phase retardation layer 540. In one or more embodiments, the difference between the refractive index of the first adhesive layer ADL1 and the refractive indices of the first phase retardation layer 520 and the second phase retardation layer 540 may be within 5%. For example, if (e.g., when) the refractive index of the second phase retardation layer 540 is n1, the refractive index of the first phase retardation layer 520 is n3, and the refractive index of the first adhesive layer ADL1 is n2, the value of Equation 1 below may be less than 0.1, for example, less than 0.05.

$$\vert ( n 1 , n 3 ) - ( n 2 ) \vert < 0.1 \qquad Equation 1$$

In one or more embodiments, the refractive index of the first adhesive layer ADL1 may be about 1.55 to about 1.7. This may indicate that the refractive index of the first adhesive layer ADL1 is equal to or substantially similar to the refractive index of the first phase retardation layer 520 and the refractive index of the second phase retardation layer 540.

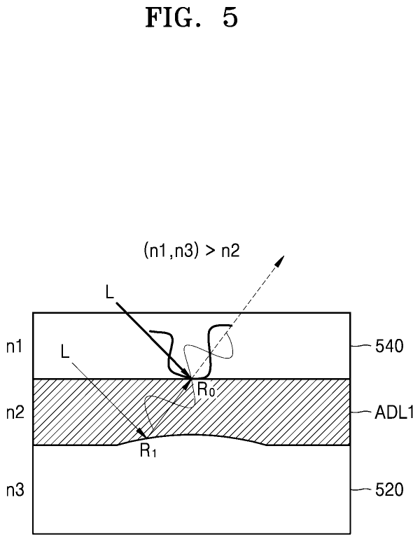

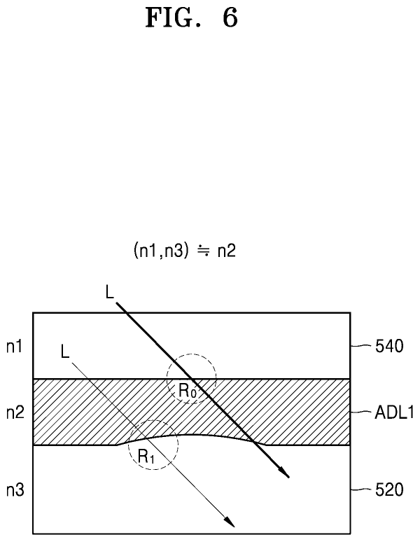

FIGS. 5 and 6 are cross-sectional views illustrating portions of polarizing films of Comparative Example and Example, respectively, and illustrating interface reflection.

Referring to FIGS. 5 and 6, a stacked structure of a second phase retardation layer 540 (refractive index: n1)/a first adhesive layer ADL1 (refractive index: n2)/a first phase retardation layer 520 (refractive index: n3) within a polarizing film is illustrated. In the first adhesive layer ADL1 between the second phase retardation layer 540 and the first phase retardation layer 520, fine bumps and/or irregularities may be formed during a process. This may be fine from several nanometers (nm) to tens of nm, but problems may occur due to interface reflection at an interlayer interface.

Referring to FIG. 5, as Comparative Example, the refractive index n2 of the first adhesive layer ADL1 may deviate from about 1.55 to about 1.7, for example, the refractive index n2 of the first adhesive layer ADL1 may be less than 1.55. In one or more embodiments, as illustrated in FIG. 5, light L incident through the polarizing layer 510 may cause interface reflection R₀ and R₁ (hereinafter Equation 2) due to the difference in refractive index at the interface between the second phase retardation layer 540 and the first adhesive layer ADL1 and the interface between the first adhesive layer ADL1 and the first phase retardation layer 520 in the stacked structure of the second phase retardation layer 540 (refractive index: n1)/the first adhesive layer ADL1 (refractive index: n2)/the first phase retardation layer 520 (refractive index: n3). Spots, such as black dots, may occur due to the destructive interference between the interface reflections R₀ and R₁ that occur at each interface, resulting in a deterioration in display quality.

$${R}_{0} = {\vert \frac{n 1 - n 2}{n 1 + n 2} \vert}^{2} \qquad Equation 2$$

$${R}_{1} = {\vert \frac{n 2 - n 3}{n 2 + n 3} \vert}^{2}$$

Referring to FIG. 6, in the display apparatus according to one or more embodiments, because the refractive index n2 of the first adhesive layer ADL1 is equal to or very similar to the refractive indices n1 and n3 of the first phase retardation layer 520 and the second phase retardation layer 540, light L incident through the polarizing layer 510 may pass through the stacked structure of the second phase retardation layer 540/the first adhesive layer ADL1/the first phase retardation layer 520, without being reflected at the interface. In the display apparatus according to one or more embodiments, because the refractive index of the first adhesive layer ADL1 is about 1.55 to about 1.7, the refractive index of the first adhesive layer ADL1 may be implemented to be equal to or very similar to the refractive indices of the first phase retardation layer 520 and the second phase retardation layer 540. Internal reflection at each interface may be suppressed (or a degree or occurrence of internal reflection at each interface may be reduced) and external visibility may be improved or enhanced.

The first adhesive layer ADL1 may be formed or provided by including a refractive index modifier in a base polymer.

In one or more embodiments, the base polymer may include at least one of an acrylic-based polymer, a rubbery polymer (e.g., natural rubber, synthetic rubber, mixtures thereof, and/or the like), a polyester-based polymer, a urethane-based polymer, a polyether-based polymer, a silicone-based polymer, a polyamide-based polymer, or a fluorine-based polymer. The base polymer may refer to a polymer that enables the first adhesive layer ADL1 to have adhesiveness and is a main or predominant component of the first adhesive layer ADL1. In one or more embodiments, in the expression “the base polymer is a main or predominant component of the first adhesive layer ADL1,” the “main or predominant component” may refer to that a component is included in an amount of about 50 wt % or more if (e.g., when) the first adhesive layer ADL1 is formed or provided. The base polymer may be included in an amount of, for example, about 50 wt % or more, about 60 wt % or more, about 70 wt % or more, about 80 wt % or more, or about 90 wt % or more.

In the present disclosure, a case where an acrylic-based polymer is used as the base polymer is described as an example, but embodiments of the present disclosure are not limited thereto, and an organic material having transmissive and adhesive characteristics, including the materials as described in one or more embodiments, may be used. The term “acrylic-based polymer” as used herein may refer to a polymer including a monomer unit derived from a monomer having at least one (meth)acryloyl group per molecule as a monomer unit that constitutes the polymer. For example, the base polymer may include one or more monomers. Different types or kinds of monomers may be added to perform or provide different functions within the first adhesive layer ADL1.

For example, the proportion of an acrylic-based monomer among all monomers used in the synthesis of acrylic-based polymers may be about 50 wt % or more, and, for example, about 70 wt % or more or about 90 wt % or more. In one or more embodiments, the term “(meth)acryloyl” as used herein comprehensively refers to acryloyl and methacryloyl, the term “(meth)acrylate” as used herein comprehensively refers to acrylate and methacrylate, and the term “(meth)acrylic” as used herein comprehensively refers to acrylic and methacrylic.

In one or more embodiments, the refractive index modifier is a material added to improve or enhance the refractive index of the first adhesive layer ADL1. The refractive index modifier may use a material having a refractive index greater than a refractive index of the adhesive layer including the refractive index modifier. For example, the refractive index modifier may be a material having a refractive index greater than a refractive index of the first adhesive layer to which the refractive index modifier is not added. In one or more embodiments, the refractive index modifier may use a material having a refractive index greater than a refractive index of the base polymer of the first adhesive layer ADL1 including the refractive index modifier. By adding the refractive index modifier to the first adhesive layer ADL1 within a set or predetermined range, relatively high refractive index and excellent or suitable adhesive performance may be ensured or provided concurrently (e.g., simultaneously).

In one or more embodiments, the refractive index modifier may be an organic material. The organic material may be a polymer and/or a non-polymer. In one or more embodiments, the refractive index modifier may or may not include a polymerizable functional group. One type or kind of refractive index modifier may be used alone, or two or more types or kinds of refractive index modifier may be used in combination.

In one or more embodiments, the refractive index of the refractive index modifier may be greater than or equal to about 1.55. In one or more embodiments, the refractive index of the refractive index modifier may be set in a relative relationship with the refractive index of the base polymer, and a material within the refractive index as described in one or more embodiments may be used without limitation. As the refractive index of the first adhesive layer ADL1 is improved or enhanced by adding the refractive index modifier, the refractive index of the refractive index modifier may be about 1.55 or more. For example, the refractive index of the refractive index modifier may be about 1.60 or more, about 1.70 or more, about 1.80 or more, or about 1.90 or more. The refractive index of the refractive index modifier may vary depending on the content (e.g., amount) of the refractive index modifier in the first adhesive layer ADL1, but a high refractive index may be suitable or desirable. There is no limitation on the upper limit of the refractive index of the refractive index modifier. However, considering the compatibility, adhesiveness, and transparency of the first adhesive layer ADL1, the refractive index of the refractive index modifier may be about 3.0 or less, about 2.5 or less, or 2.0 or less. The refractive index of the refractive index modifier according to the present disclosure may be, for example, about 1.55 to about 2.0.

In one or more embodiments, the amount of the refractive index modifier used based on 100 wt % of the base polymer may be set as required or desired. From the viewpoint of increasing or enhancing the refractive index of the adhesive, the amount of the refractive index modifier used based on 100 wt % of the base polymer may be, for example, about 1 wt % or more, about 3 wt % or more, about 5 wt % or more, about 7 wt % or more, about 10 wt % or more, about 15 wt % or more, or about 20 wt % or more. In one or more embodiments, the amount of the refractive index modifier used based on 100 wt % of the base polymer may be, for example, less than about 50 wt %. If (e.g., when) the refractive index modifier is added in an amount of about 50 wt % or more, it may be advantageous or beneficial to increase or enhance the refractive index of the first adhesive layer ADL1, but adhesive strength or optical characteristics may deteriorate or reduce. In one or more embodiments, it may be desirable to add the refractive index modifier appropriately or suitably. In one or more embodiments, the amount of the refractive index modifier used based on 100 wt % of the base polymer may be, for example, about 45 wt % or less, about 30 wt % or less, about 20 wt % or less, about 15 wt % or less, about 10 wt % or less, about 5 wt % or less, or about 3 wt % or less.

In one or more embodiments, the refractive index modifier may include an organic compound having an aromatic ring. At least one substituent may be bonded to the aromatic ring. In one or more embodiments, no substituent may be bonded to the aromatic ring. The substituent may include, for example, an alkyl group, an alkoxy group, an aryloxy group, a hydroxyl group, a halogen atom (a fluorine atom, a chlorine atom, a bromine atom, and/or an iodine atom), a hydroxyalkyl group, a hydroxy alkyloxy group, and/or a glycidyloxy group, but embodiments of the present disclosure are not limited thereto. In a substituent including carbon atoms, the number of carbon atoms included in the substituent may be, for example, 1 to 10, 1 to 6, 1 to 4, 1 to 3, or 1 or 2. For example, the aromatic ring may be an aromatic material having no substituent or having at least one substituent selected from among an alkyl group, an alkoxy group, and a halogen atom (e.g., a bromine atom).

Group 1 represents compounds as an example of the refractive index modifier. The refractive index modifier may include, for example, at least one selected from among 9,9-bis(4-hydroxyphenyl)fluorene, 9,9-bis(4-aminophenyl)fluorene, 6-acryloyloxy methyl dinaphthothiophene, 6-methacryloyloxy methyl zinaphthothiophene, 5-acryloyloxy ethyl dinaphthothiophene, 6-acryloyloxy ethyl dinaphthothiophene, 6-vinyl dinaphthothiophene, 5-vinyl dinaphthothiophene, and 2,12-diarylooxyginafutothiophene.

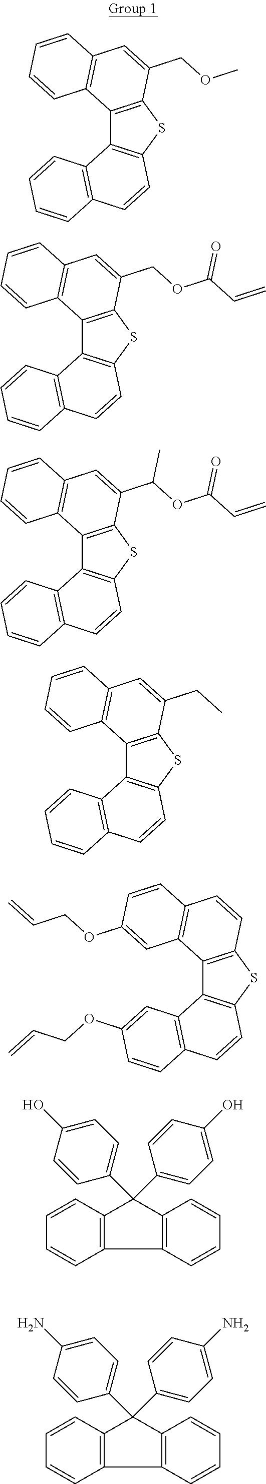

Referring to FIG. 3, the second adhesive layer ADL2 may be between the second phase retardation layer 540 and the first protective layer 530. The second adhesive layer ADL2 may be a PSA. For example, the second adhesive layer ADL2 may be an acrylic-based PAS.

In one or more embodiments, the refractive index of the second adhesive layer ADL2 may be about 1.5 or less. For example, the refractive index of the second adhesive layer ADL2 may be about 1.49 or less, about 1.48 or less, or about 1.47 or less. In one or more embodiments, the refractive index of the first adhesive layer ADL1 may be greater than the refractive index of the second adhesive layer ADL2. Because the second adhesive layer ADL2 is above the first phase retardation layer 520, it may not affect interface reflection due to light that passes through the first phase retardation layer 520, as described in one or more embodiments. In one or more embodiments, the second adhesive layer ADL2 may use any suitable adhesive material that is generally available or generally used. For example, a material having a refractive index of about 1.5 or less may be used.

The first protective layer 530 and the second protective layer 550 may be respectively on one surface and the other surface of the polarizing layer 510 with the polarizing layer 510 therebetween. The first protective layer 530 may be on the lower surface of the polarizing layer 510, and the second protective layer 550 may be on the upper surface of the polarizing layer 510. The first protective layer 530 and the second protective layer 550 may support the polarizing layer 510 and supplement or increase the mechanical strength of the polarizing layer 510. Each of the first protective layer 530 and the second protective layer 550 may include TAC, a cycloolefin polymer, PMMA, PET, and/or the like.

The hard coating layer HC may protect the configuration or arrangement of the polarizing film 20 from external impact and may be on the uppermost portion of the polarizing film 20. The hard coating layer HC may have a scratch prevention function and may have a strength of about 9H according to the pencil hardness scale.

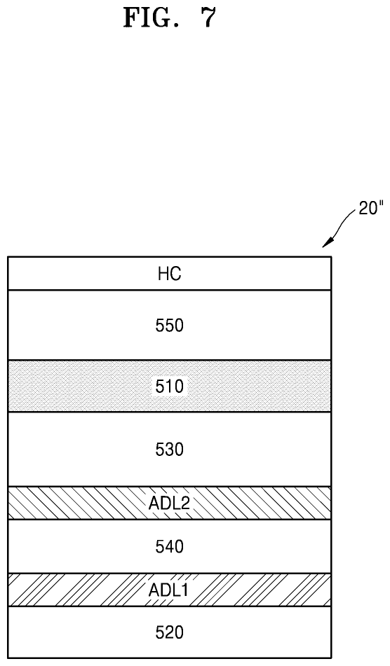

FIG. 7 is a schematic cross-sectional view of a polarizing film 20″ according to one or more embodiments.

The stacked structure of the polarizing film 20″ of FIG. 7 is substantially the same as the stacked structure of the polarizing film 20 of FIG. 3 as described in one or more embodiments. In the polarizing film 20″ of FIG. 7, a first adhesive layer ADL1 may include a refractive index modifier in a base polymer, as described in one or more embodiments, and may further include an ultraviolet (UV) curable material. The first adhesive layer ADL1 may be an UV optically clear (e.g., substantially clear) resin (OCR). In one or more embodiments, the configuration or arrangement of the first adhesive layer ADL1 and other layers may be substantially the same as the configuration or arrangement of the polarizing film 20 of FIG. 3 as described in one or more embodiments, and thus, a redundant description thereof may not be provided.

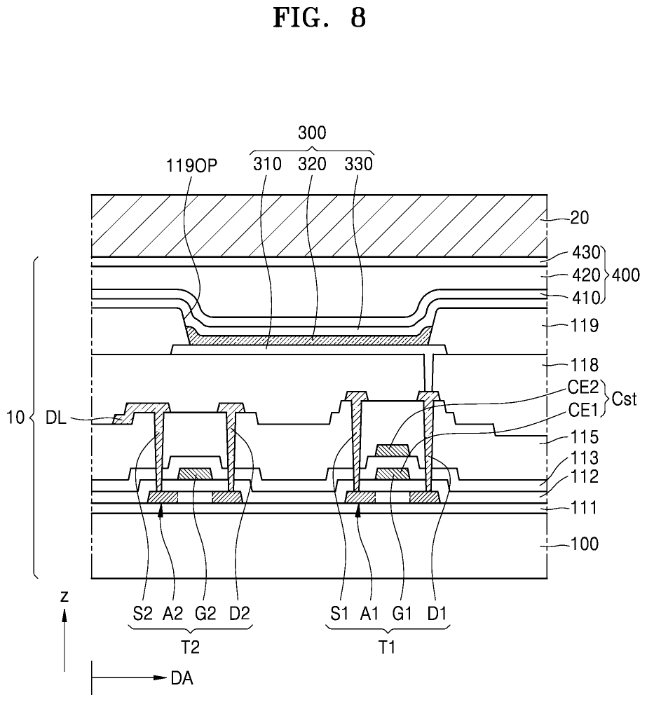

FIG. 8 is a schematic cross-sectional view of a portion of a display apparatus according to one or more embodiments.

Referring to FIG. 8, the display apparatus may include a substrate 100, a first thin-film transistor T1 and a second thin-film transistor T2 that are disposed or provided on the substrate 100, and an organic light-emitting diode 300 electrically connected to the first thin-film transistor T1 and the second thin-film transistor T2. In one or more embodiments, the display apparatus may further include one or more suitable insulating layers 111, 112, 113, 115, 118, and 119 and a storage capacitor Cst.

The substrate 100 may include one or more suitable materials, such as glass, metal, and/or plastic. In one or more embodiments, the substrate 100 may be a flexible substrate. For example, the substrate 100 may include a polymer resin, such as polyethersulfone (PES), polyacrylate (PAR), polyetherimide (PEI), polyethylene naphthalate (PEN), PET, polyphenylene sulfide (PPS), polyarylate, polyimide (PI), polycarbonate, and/or cellulose acetate propionate (CAP).

The buffer layer 111 may be on the substrate 100. The buffer layer 111 may prevent infiltration (or reduce a degree or occurrence of infiltration) of foreign material, moisture, and/or ambient air from below the substrate 100 and may provide a flat (e.g., substantially flat) surface on the substrate 100. The buffer layer 111 may include an inorganic material, such as an oxide and/or a nitride, an organic material, and/or an organic/inorganic composite material and may have a single-layer or a multilayer structure including an inorganic material and/or an organic material. A barrier layer that prevents infiltration (or reduces a degree or occurrence of infiltration) of ambient air may be further included between the substrate 100 and the buffer layer 111. In one or more embodiments, the buffer layer 111 may include silicon oxide (e.g., SiO₂) and/or silicon nitride (e.g., SiN_{X} or Si₃N₄).

The first thin-film transistor T1 and/or the second thin-film transistor T2 may be on the buffer layer 111. The first thin-film transistor T1 may include a semiconductor layer A1, a gate electrode G1, a source electrode S1, and a drain electrode D1, and the second thin-film transistor T2 may include a semiconductor layer A2, a gate electrode G2, a source electrode S2, and a drain electrode D2. The first thin-film transistor T1 may be connected to the organic light-emitting diode 300 and function or serve as a driving thin-film transistor configured or arranged to drive the organic light-emitting diode 300. The second thin-film transistor T2 may be connected to a data line DL and function or serve as a switching thin-film transistor. The two thin-film transistors are illustrated, but embodiments of the present disclosure are not limited thereto. The number of thin-film transistors may vary from 1 to 7.

Each of the semiconductor layers A1 and A2 may include amorphous (e.g., non-crystalline) silicon and/or polycrystalline silicon. In one or more embodiments, each of the semiconductor layers A1 and A2 may include an oxide of at least one selected from among indium (In), gallium (Ga), stannum or tin (Sn), zirconium (Zr), vanadium (V), hafnium (Hf), cadmium (Cd), germanium (Ge), chromium (Cr), titanium (Ti), and zinc (Zn). Each of the semiconductor layers A1 and A2 may include a channel region, and a source region and a drain region doped with impurities.

The gate electrodes G1 and G2 may be respectively on the semiconductor layers A1 and A2 with the first gate insulating layer 112 therebetween. Each of the gate electrodes G1 and G2 may include molybdenum (Mo), aluminum (Al), copper (Cu), titanium (Ti), and/or the like and may include a single layer or layers. For example, each of the gate electrodes G1 and G2 may be a single Mo layer.

The first gate insulating layer 112 may include silicon oxide (e.g., SiO₂), silicon nitride (e.g., SiNₓ or Si₃N₄), silicon oxynitride (e.g., SiON or Si₂ON₂), aluminum oxide (e.g., Al₂O₃), titanium oxide (e.g., TiO₂), tantalum oxide (e.g., Ta₂O₅), hafnium oxide (e.g., HfO₂), and/or zinc oxide (e.g., ZnO₂).

The second gate insulating layer 113 may be disposed or provided to cover the gate electrodes G1 and G2. The second gate insulating layer 113 may include silicon oxide (e.g., SiO₂), silicon nitride (e.g., SiNₓ or Si₃N₄), silicon oxynitride (e.g., SiON or Si₂ON₂), aluminum oxide (e.g., Al₂O₃), titanium oxide (e.g., TiO₂), tantalum oxide (e.g., Ta₂O₅), hafnium oxide (e.g., HfO₂), and/or zinc oxide (e.g., ZnO₂).

A first storage electrode CE1 of the storage capacitor Cst may overlap with the first thin-film transistor T1. For example, the gate electrode G1 of the first thin-film transistor T1 may function or serve as the first storage electrode CE1 of the storage capacitor Cst. However, embodiments of the present disclosure are not limited thereto. The storage capacitor Cst may be apart from the first thin-film transistor T1 and the second thin-film transistor T2 without overlapping the first thin-film transistor T1.

A second storage electrode CE2 of the storage capacitor Cst may overlap the first storage electrode CE1 with the second gate insulating layer 113 therebetween. In one or more embodiments, the second gate insulating layer 113 may function or serve as a dielectric layer of the storage capacitor Cst. The second storage electrode CE2 may include a conductive (e.g., electrically conductive) material including molybdenum (Mo), aluminum (Al), copper (Cu), titanium (Ti), and/or the like, and may include a single layer or layers including the conductive (e.g., electrically conductive) material as described in one or more embodiments. For example, the second storage electrode CE2 may be a single Mo layer or a multilayer of Mo/Al/Mo.

The interlayer insulating layer 115 may be on the entire surface of the substrate 100 to cover the second storage electrode CE2. The interlayer insulating layer 115 may include silicon oxide (e.g., SiO₂), silicon nitride (e.g., SiNₓ or Si₃N₄), silicon oxynitride (e.g., SiON or Si₂ON₂), aluminum oxide (e.g., Al₂O₃), titanium oxide (e.g., TiO₂), tantalum oxide (e.g., Ta₂O₅), hafnium oxide (e.g., HfO₂), and/or zinc oxide (e.g., ZnOₓ).

The source electrodes S1 and S2 and the drain electrodes D1 and D2 may be on the interlayer insulating layer 115. Each of the source electrodes S1 and S2 and the drain electrodes D1 and D2 may include a conductive (e.g., electrically conductive) material including molybdenum (Mo), aluminum (Al), copper (Cu), titanium (Ti), and/or the like and may include a single layer or layers including the conductive (e.g., electrically conductive) material as described in one or more embodiments. For example, each of the source electrodes S1 and S2 and the drain electrodes D1 and D2 may have a multilayer structure of Ti/Al/Ti.

The planarization layer 118 may be on the source electrodes S1 and S2 and the drain electrodes D1 and D2, and the organic light-emitting diode 300 may be on the planarization layer 118. The organic light-emitting diode 300 may include a first electrode 310, an intermediate layer 320 including an organic emission layer, and a second electrode 330.

The planarization layer 118 may have a flat (e.g., substantially flat) upper surface so that the first electrode 310 is formed or provided to be flat (e.g., substantially flat). The planarization layer 118 may include a single layer or layers including an organic material and/or an inorganic material. The planarization layer 118 may include general-purpose polymer (e.g., benzocyclobutene (BCB), polyimide, hexamethyldisiloxane (HMDSO), polymethylmethacrylate (PMMA), and/or polystyrene (PS)), polymer derivatives having a phenolic group, an acrylic-based polymer, an imide-based polymer, an aryl ether-based polymer, an amide-based polymer, a fluorine-based polymer, a p-xylene-based polymer, a vinyl alcohol-based polymer, or any blend thereof. In one or more embodiments, the planarization layer 118 may include silicon oxide (e.g., SiO₂), silicon nitride (e.g., SiNₓ or Si₃N₄), silicon oxynitride (e.g., SiON or Si₂ON₂), aluminum oxide (e.g., Al₂O₃), titanium oxide (e.g., TiO₂), tantalum oxide (e.g., Ta₂O₅), hafnium oxide (e.g., HfO₂), and/or zinc oxide (e.g., ZnO₂). After forming or providing the planarization layer 118, chemical mechanical polishing may be performed thereon to provide a flat (e.g., substantially flat) upper surface.

The planarization layer 118 may have an opening that exposes one of the source electrode S1 and the drain electrode D1 of the first thin-film transistor T1, and the first electrode 310 may be electrically connected to the first thin-film transistor T1 in contact with the source electrode S1 or the drain electrode D1 through the opening.

The first electrode 310 may include a conductive (e.g., electrically conductive) oxide, such as indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the first electrode 310 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In one or more embodiments, the first electrode 310 may further include a layer including ITO, IZO, ZnO, and/or In₂O₃ above and/or below the reflective layer. For example, the first electrode 310 may have a single-layer structure consisting of a single layer or a multilayer structure including a plurality of layers. For example, the first electrode 310 may have a three-layer structure of ITO/Ag/ITO.

The pixel defining layer 119 may be on the first electrode 310. The pixel defining layer 119 may have an opening 119OP that corresponds to each sub-pixel, for example, the opening 119OP that exposes at least the central portion of the first electrode 310, and thus, may serve to define a pixel. In one or more embodiments, the pixel defining layer 119 may prevent an electric arc and/or the like from occurring (or reduce a degree to or occurrence of which an electric arc and/or the like occurs) between the edge of the first electrode 310 and the second electrode 330 by increasing the distance between the edge of the first electrode 310 and the second electrode 330. The pixel defining layer 119 may include, for example, an organic material, such as polyimide and/or HMDSO.

A spacer may be on the pixel defining layer 119. The spacer may be used to prevent a mask from being damaged (or reduce a degree to or occurrence of which a mask gets damaged) during a mask process necessary to form or provide the intermediate layer 320 of the organic light-emitting diode 300. The spacer may include, for example, an organic material, such as polyimide and/or HMDSO. The spacer and the pixel defining layer 119 may be concurrently (e.g., simultaneously) formed or provided by using substantially the same material. In one or more embodiments, a half-tone mask may be used.

The intermediate layer 320 of the organic light-emitting diode 300 may include an organic emission layer. The organic emission layer may include an organic material including a fluorescent material and/or a phosphorescent material that emit red light, green light, blue light, or white light. The organic emission layer may include a low molecular weight organic material and/or a high molecular weight organic material. Functional layers, such as a hole transport layer (HTL), a hole injection layer (HIL), an electron transport layer (ETL), and an electron injection layer (EIL), may be optionally disposed or provided below and above the organic emission layer. The intermediate layer 320 may be disposed or provided to correspond to each of a plurality of first electrodes 310. However, embodiments of the present disclosure are not limited thereto. The intermediate layer 320 may be suitably modified. For example, the intermediate layer 320 may include a layer integrally formed or provided as a single body across the first electrodes 310.

The second electrode 330 may be a transmissive electrode or a reflective electrode. In one or more embodiments, the second electrode 330 may be a transparent electrode or a semitransparent electrode. The second electrode 330 may include a metal thin-film having a low work function and including Li, Ca, LiF/Ca, LiF/Al, Al, Ag, Mg, or any compound thereof. In one or more embodiments, a transparent (e.g., substantially transparent) conductive (e.g., electrically conductive) oxide (TCO) layer, such as ITO, IZO, ZnO, and/or In₂O₃, may be further disposed or provided on the metal thin-film. The second electrode 330 may be disposed or provided across the display area DA and peripheral area PA as described in one or more embodiments with reference to FIG. 1 and may be disposed or provided above the intermediate layer 320 and the pixel defining layer 119. The second electrode 330 may be integrally formed or provided as a single body in a plurality of organic light-emitting diodes 300 and may correspond to a plurality of first electrodes 310.

A thin-film encapsulation layer 400 that seals the display area DA may be further included on the organic light-emitting diode 300. The thin-film encapsulation layer 400 may cover the display area DA and protect the organic light-emitting diode 300 from ambient moisture and/or oxygen. In one or more embodiments, the encapsulation layer 400 may include a first inorganic encapsulation layer 410, an organic encapsulation layer 420, and a second inorganic encapsulation layer 430.

The first inorganic encapsulation layer 410 may cover the second electrode 330 and may include ceramic, metal oxide, metal nitride, metal carbide, metal oxynitride, indium oxide (e.g., In₂O₃), tin oxide (e.g., SnO₂), ITO, silicon oxide (e.g., SiO₂), silicon nitride (e.g., SiNₓ or Si₃N₄), and/or silicon oxynitride (e.g., SiON or Si₂ON₂). Other layers, such as a capping layer, may be between the first inorganic encapsulation layer 410 and the second electrode 330 as necessary or desired. Because the first inorganic encapsulation layer 410 is along the underlying structure, the upper surface of the first inorganic encapsulation layer 410 may not be flat, as illustrated in FIG. 8.

The organic encapsulation layer 420 may cover the first inorganic encapsulation layer 410. Unlike the first inorganic encapsulation layer 410, the upper surface of the organic encapsulation layer 420 may be substantially flat. For example, the organic encapsulation layer 420 may have a substantially flat upper surface in a portion that corresponds to the display area DA. The organic encapsulation layer 420 may include at least one selected from among acrylic, methacrylic, polyester, polyethylene, polypropylene, PET, polyethylene naphthalate, polycarbonate, polyimide, polyethylene sulfonate, polyoxymethylene, polyarylate, and hexamethyldisiloxane.

The second inorganic encapsulation layer 430 may cover the organic encapsulation layer 420 and may include ceramic, metal oxide, metal nitride, metal carbide, metal oxynitride, indium oxide (e.g., In₂O₃), tin oxide (e.g., SnO₂), ITO, silicon oxide (e.g., SiO₂), silicon nitride (e.g., SiNₓ or Si₃N₄), and/or silicon oxynitride (e.g., SiON or Si₂ON₂). The second inorganic encapsulation layer 430 may be in contact with the first inorganic encapsulation layer 410 at the edge thereof located or provided outside the display area DA, so that the organic encapsulation layer 420 may not be exposed to the outside.

The thin-film encapsulation layer 400 may include the first inorganic encapsulation layer 410, the organic encapsulation layer 420, and the second inorganic encapsulation layer 430, and thus, even if (e.g., when) cracks occur within the thin-film encapsulation layer 400 through the multilayer structure, such cracks may be prevented from being connected to each other between the first inorganic encapsulation layer 410 and the organic encapsulation layer 420 or between the organic encapsulation layer 420 and the second inorganic encapsulation layer 430. This may prevent the formation of a path (or reduce a degree or occurrence of the formation of a path) through which ambient moisture and/or oxygen penetrates into the display area DA.

In the present disclosure, a case where the thin-film encapsulation layer 400 is used as an encapsulation member to seal the organic light-emitting diode 300 is illustrated, but embodiments of the present disclosure are not limited thereto. For example, as the member to seal the organic light-emitting diode 300, a sealing substrate that is attached to the substrate 100 by a sealant and/or frit may be used.

In the present disclosure, a polarizing film 20 may be on the thin-film encapsulation layer 400 and/or on the sealing substrate so as to improve or enhance outdoor visibility. As described with reference to FIG. 2, the third adhesive layer 12 may be further disposed or provided between the thin-film encapsulation layer 400 and the polarizing film 20.

As described with reference to FIG. 3, the polarizing film 20 may include the polarizing layer 510, the first phase retardation layer 520, the second phase retardation layer 540, the first protective layer 530, the second protective layer 550, the hard coating layer HC, the first adhesive layer ADL1 between the first phase retardation layer 520 and the second phase retardation layer 540, and the second adhesive layer ADL2 on the second phase retardation layer 540.

One or more suitable functional layers, such as a touch screen layer and/or a window, may be further included on the thin-film encapsulation layer 400, for example, on the polarizing film 20, and a capping layer may be further included between the second electrode 330 and the thin-film encapsulation layer 400 so as to improve or enhance light efficiency.

Table 1 compares defect rates between Example that employs or utilizes the polarizing film according to one or more embodiments and Comparative Example.

TABLE 1

| | |
|---|---|
| Spot Mura | Dot Mura |

| | strong | medium | weak | medium | weak |
|---|---|---|---|---|---|
| Comparative | 13% | 10% | 15% | 10% | 9% |
| Example | | | | | |
| Example | 0% | 0% | 0% | 0% | 0% |

In Table 1 the display apparatus of Example is a display apparatus that employs the polarizing film 20 as described with reference to FIGS. 3, 5, and 6, and has the first adhesive layer ADL1 including the refractive index modifier with a high refractive index. Therefore, the refractive index of the first adhesive layer ADL1 included in Example is about 1.58, which is within a range of about 1.55 to about 2.0, as described in one or more embodiments. On the other hand, the display apparatus of Comparative Example has substantially the same stacked structure as the polarizing films 20 and 20′ as described with reference to FIGS. 3 to 6, but employs a polarizing film including a first adhesive layer that does not include a refractive index modifier. The first adhesive layer of Comparative Example does not include the refractive index modifier, and thus, may have a refractive index lower than a refractive index of the first adhesive layer ADL1 of Example. Therefore, the refractive index of the first adhesive layer included in Comparative Example is about 1.47.

As shown in the experimental result of Table 1, in the case of Comparative Example, the refractive index of the first adhesive layer is different from the refractive indices (e.g., about 1.6 to about 1.7) of the first and second phase retardation layers above and below the first adhesive layer, and thus, interface reflection occurs due to the difference in refractive index and the occurrence rate of defects, such as mura, is 50% or greater. On the other hand, the first adhesive layer ADL1 according to Example has the refractive index equal to or substantially similar to the refractive indices (e.g., about 1.6 to about 1.7) of the first and second phase retardation layers above and below the first adhesive layer within 1.55 to 2.0. Therefore, it may be confirmed that interface reflection due to the difference in refractive index hardly occurs, and thus, defects, such as mura, do not occur.

The display apparatus has been mainly or predominantly described in one or more embodiments, but embodiments of the present disclosure are not limited thereto. For example, it may be stated that a method of manufacturing the display apparatus also falls within the scope of the present disclosure.

According to one or more embodiments, a polarizing film, which protects a screen from external light reflection (or reduces a degree to or occurrence of which a screen reflects external light) so as to display high-quality images, and a display apparatus including the polarizing film may be implemented. The scope of the present disclosure is not limited by such an effect.

One or more embodiments of the present disclosure provide an electronic device including the display apparatus as described in one or more embodiments.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure has been described with reference to the figures, it will be understood by those of ordinary skill in the art that one or more suitable changes in form and more details may be made therein without departing from the spirit and scope as defined by the following claims and equivalents thereof.

What is claimed is:

1. A display apparatus, comprising:
a display panel comprising a display element; and
a polarizing film on the display panel,
wherein the polarizing film comprises:
a first phase retardation layer;
a second phase retardation layer on the first phase retardation layer;
a first adhesive layer between the first phase retardation layer and the second phase retardation layer;
a second adhesive layer on the second phase retardation layer;
a first protective layer on the second adhesive layer;
a second protective layer on the first protective layer; and
a polarizing layer between the first protective layer and the second protective layer,
wherein a refractive index of the first adhesive layer is about 1.55 to about 1.7.

2. The display apparatus as claimed in claim 1, wherein a thickness of the first adhesive layer is about 5 μm to about 10 μm.

3. The display apparatus as claimed in claim 1, wherein the first phase retardation layer comprises a quarter-wave plate (QWP) and the second phase retardation layer comprises a half-wave plate (HWP).

4. The display apparatus as claimed in claim 1, wherein the first phase retardation layer comprises a positive C plate and the second phase retardation layer comprises an HWP.

5. The display apparatus as claimed in claim 1, wherein the first phase retardation layer comprises a positive A plate and the second phase retardation layer comprises a negative A plate, and wherein the first adhesive layer is on a surface of the first phase retardation layer, and a phase compensation layer is on another surface of the first phase retardation layer.

6. The display apparatus as claimed in claim 1, wherein the phase compensation layer comprises a positive C plate.

7. The display apparatus as claimed in claim 1, wherein the first adhesive layer comprises a base polymer and a refractive index modifier, and the refractive index modifier comprises a compound having an aromatic ring, and wherein a refractive index of the refractive index modifier is about 1.55 to about 2.0.

8. The display apparatus as claimed in claim 7, wherein the refractive index modifier comprises at least one selected from among 9,9-bis(4-hydroxyphenyl)fluorene, 9,9-bis(4-aminophenyl)fluorene, 6-acryloyloxy methyl dinaphthothiophene, 6-methacryloyloxy methyl zinaphthothiophene, 5-acryloyloxy ethyl dinaphthothiophene, 6-acryloyloxy ethyl dinaphthothiophene, 6-vinyl dinaphthothiophene, 5-vinyl dinaphthothiophene, and 2,12-diarylooxyginafutothiophene.

9. The display apparatus as claimed in claim 1, wherein the first adhesive layer has a refractive index greater than a refractive index of the second adhesive layer.

10. The display apparatus as claimed in claim 1, wherein a refractive index of each of the first phase retardation layer and the second phase retardation layer is about 1.6 to about 1.7.

11. The display apparatus as claimed in claim 1, wherein the first adhesive layer further comprises an ultraviolet (UV) curable material.

12. A polarizing film, comprising:
a first phase retardation layer;
a second phase retardation layer on the first phase retardation layer;
a first adhesive layer between the first phase retardation layer and the second phase retardation layer;
a second adhesive layer on the second phase retardation layer;
a first protective layer on the second adhesive layer;
a second protective layer on the first protective layer; and
a polarizing layer between the first protective layer and the second protective layer,
wherein a refractive index of the first adhesive layer is about 1.55 to about 1.7.

13. The polarizing film as claimed in claim 12, wherein the first adhesive layer comprises a base polymer and a refractive index modifier, and the refractive index modifier comprises a compound having an aromatic ring.

14. The polarizing film as claimed in claim 12, wherein a refractive index of the refractive index modifier is about 1.55 to about 2.0.

15. The polarizing film as claimed in claim 14, wherein the refractive index modifier comprises at least one selected from among 9,9-bis(4-hydroxyphenyl)fluorene, 9,9-bis(4-aminophenyl)fluorene, 6-acryloyloxy methyl dinaphthothiophene, 6-methacryloyloxy methyl zinaphthothiophene, 5-acryloyloxy ethyl dinaphthothiophene, 6-acryloyloxy ethyl dinaphthothiophene, 6-vinyl dinaphthothiophene, 5-vinyl dinaphthothiophene, and 2,12-diarylooxyginafutothiophene.

16. The polarizing film as claimed in claim 12, wherein the first adhesive layer has a refractive index greater than a refractive index of the second adhesive layer.

17. The polarizing film as claimed in claim 12, wherein a refractive index of each of the first phase retardation layer and the second phase retardation layer is about 1.6 to about 1.7.

18. The polarizing film as claimed in claim 12, wherein the first adhesive layer further comprises an ultraviolet (UV) curable material.

19. An electronic device, comprising a display apparatus comprising:
a display panel comprising a display element; and
a polarizing film on the display panel,
wherein the polarizing film comprises:
a first phase retardation layer;
a second phase retardation layer on the first phase retardation layer;
a first adhesive layer between the first phase retardation layer and the second phase retardation layer;
a second adhesive layer on the second phase retardation layer;
a first protective layer on the second adhesive layer;
a second protective layer on the first protective layer; and
a polarizing layer between the first protective layer and the second protective layer,
wherein a refractive index of the first adhesive layer is about 1.55 to about 1.7.

20. The electronic device as claimed in claim 19, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
